(19) United States
(12) Patent Application Publication
(10) Pub. No.: US 2010/0207520 A1
(43) Pub. Date: Aug. 19, 2010

(54) LIGHT EMISSIVE DEVICE STRUCTURE AND A METHOD OF FABRICATING THE SAME

(76) Inventors: Furong Zhu, Singapore (SG); Li Wei Tan, Singapore (SG); Pooi Kwan Liew, Singapore (SG); Kian Soo Ong, Singapore (SG)

Correspondence Address: MICHAEL W. TAYLOR, P.O. BOX 3791, ORLANDO, FL, 32802-3791, US

(21) Appl. No.: 12/594,338

(22) PCT Filed: Apr. 4, 2008
(86) PCT No.: PCT/SG08/00109

§ 371 Date: Mar. 26, 2010

Related U.S. Application Data
(60) Provisional application No. 60/910,066, filed on Apr. 4, 2007.

(51) Int. Cl. H01L 51/52; H01L 51/56

(52) U.S. Cl. 313/506; 445/33

(57) ABSTRACT

A light emissive device structure and a method for forming a light emissive device structure are provided. The structure comprises a transparent substrate; a transparent electrode formed on the transparent substrate; one or more light emitting layers formed on the first transparent electrode; a reflective electrode formed on the one or more light emitting layers; and a textured layer formed on the transparent substrate for enhancing light contrast of the device. Advantageously, the structure further comprises a gradient refractive index layer.

### FIELD OF INVENTION

The present invention relates broadly to a light emissive device structure and to a method for forming a light emissive device structure.

### BACKGROUND

An organic/polymer light-emitting device (OLED/PLED) is typically a thin film emissive device comprising layers of inorganic electrodes and functional organic/polymeric semiconductors. A stack of functional organic layers is typically sandwiched between an upper electrode and a bottom electrode. When an OLED/PLED device is electrically biased, electrons and holes can be injected from the respective electrodes into the device. The electron-hole pairs recombine in an emissive region of the device to emit light. The light emitted in an OLED/PLED is typically isotropic.

A metallic cathode is typically used to reflect the light emitted in an electroluminescent layer (EL) towards a transparent anode/substrate. Devices having such a configuration typically have low contrast ratios and the visual image of such devices is typically poorly legible. Therefore, it has been recognized by the inventors that reduction of ambient light reflection from an emissive device is desired for e.g. high contrast OLED/PLED displays.

Circular polarizers are typically used to enhance the contrast ratios in OLED/PLED displays. However, circular polarizers are expensive and polarize the emissive light. Further, an additional bonding step is typically required in the display fabrication process to install the circular polarizers, thus incurring an extra cost to production of OLED based displays.

In addition to using circular polarizers, the feasibility of employing a low reflectivity cathode to reduce ambient reflection for achieving low reflectivity OLEDs or PLEDs has been investigated. In U.S. Pat. No. 6,429,451, Hung and Madathil demonstrated that calcium hexaboride (CaB₆) can be used as an ambient light reduction cathode. CaB₆ is highly conductive with a low work function and is substantially black in bulk form. However, although the alternative electron injection layer of CaB₆ has low reflectivity, obtaining a uniform CaB₆ film with stable optical and electrical properties is practically difficult in the deposition process.

Further, a variety of multilayer black cathode structures have also been developed to minimize light reflection at organic/cathode interfaces. For example, in U.S. Pat. No. 6,429,451 and in L. S. Hung and J. Madathil, Adv. Mater., 13 (2001) 1787, a reflection-less OLED with a multilayer black cathode structure of LiF/Al/ZnO/Al was reported. To form this multilayer black cathode, an oxygen deficient zinc oxide film was deposited by thermal evaporation. The zinc oxide film acts as an optical absorbing layer to reduce the ambient light reflection from the metallic cathode. However, one disadvantage is that the evaporated ZnO typically has poor electric conductivity leading to an increase in the contact resistance and hence the turn-on voltage. O. Renault, O. V. Salata, M. Etchells, P. J. Dobson and V. Christou, Thin Solid Films, 379 (2000) 195 also demonstrated the use of a high conductive black carbon film in a multilayer cathode system. This black cathode comprises a thin electron injector layer of magnesium, an optically absorbing and electrically conductive carbon layer and a thick aluminium layer. This multilayered black cathode has a similar charge injection property as compared to a typical Mg/Al cathode but has a much lower reflectivity. The results by Renault et. al. show that light reflection is reduced from about 100% for devices using typical cathodes to about 60% for the multilayer cathode. H. Aziz, Y. F. Liew, H. M. Grandin and Z. D. Popovic, Appl. Phys. Lett., 83 (2003) 186 has also proposed using a black cathode comprising conductive light-absorbing layers with mixtures of organic materials and metals. However, the above black cathodes are essentially applicable for only small molecule OLEDs.

In addition, based on a concept of using an interference destructive layer in a low reflectivity cathode for OLEDs as reported in A. N. Krasnov, Information Display, Vol. 18, No. 3, (2002) 18 and U.S. Pat. No. 6,411,019, Luxell Technologies has developed “Black Layer”. The above technology used deposition of CrSiO on ITO to create an interference layer. However, as the technology has a very narrow process window, ie. a 5% variation in the interference layer thickness resulted in a factor of 2 change in the reflectance, this technology has very limited success.

Further, based on WO02/37568 and WO02/37580, it has been demonstrated that the usage of a volume or surface diffuser can enable reduction of total internal reflection and can also enhance the brightness of an emissive device. In addition, EP1383180A2 and US20040012328A1 reported the use of an indium tin oxide (ITO) layer with grating patterns for improving the contrast ratio of an OLED display. However, this technique typically involves a number of critical process steps during device fabrication, thus making it practically difficult to perform.

Hence, there exists a need for a light emissive device structure and a method for forming a light emissive device structure which seek to address at least one of the above problems.

### SUMMARY

In accordance with an aspect of the present invention, there is provided a light emissive device structure, the structure comprising, a transparent substrate; a transparent electrode formed on the transparent substrate; one or more light emitting layers formed on the transparent electrode; a reflective electrode formed on the one or more light emitting layers; and a textured layer formed on the transparent substrate for enhancing light contrast of the device.

The structure may further comprise a gradient refractive index layer.

The gradient refractive index layer may be capable of suppressing light reflection of the light emissive device structure.

The gradient refractive index layer may function as the transparent electrode.

The gradient refractive index layer may comprise a transparent conducting oxide (TCO) layer.

The TCO layer may comprise an oxygen deficient TCO material.

The textured layer may be formed on an outer surface of the transparent substrate.

The textured layer may be formed as a surface modification of the transparent substrate.

The textured layer may be textured using a chemical technique, physical technique or both.

In accordance with another aspect of the present invention, there is provided a method for forming a light emissive device structure, the method comprising, providing a transparent substrate; forming a transparent electrode on the transparent substrate; forming one or more light emitting layers on the transparent electrode; forming a reflective electrode on the one or more light emitting layers; and forming a textured layer on the transparent substrate for enhancing light contrast of the device.

The method may further comprise forming a gradient refractive index layer.

The gradient refractive index layer may be capable of suppressing light reflection of the light emissive device structure.

The gradient refractive index layer may function as the transparent electrode.

The gradient refractive index layer may comprise a transparent conducting oxide (TCO) layer.

The TCO layer may comprise an oxygen deficient TCO material.

The textured layer may be formed on an outer surface of the transparent substrate.

The textured layer may be formed as a surface modification of the transparent substrate.

The textured layer may be textured using a chemical technique, physical technique or both.

### BRIEF DESCRIPTION OF THE DRAWINGS

Embodiments of the invention will be better understood and readily apparent to one of ordinary skill in the art from the following written description, by way of example only, and in conjunction with the drawings, in which:

FIG. 1 is a schematic side view diagram of an organic light emitting device (OLED) in a preferred example embodiment.

FIG. 2 is a schematic diagram illustrating a bead blasting technique in an example embodiment.

FIG. 3(a) is a schematic side view diagram showing a surface having a surface roughness of tenths of a micro-inch.

FIG. 3(b) is a schematic side view diagram showing a surface having a surface roughness of hundreds of a micro-inch.

FIG. 4 is a graph illustrating measurement of average roughness Ra.

FIG. 5(a) is a schematic diagram illustrating a sample control OLED structure comprising a normal ITO anode formed on a flat glass substrate.

FIG. 5(b) is a schematic diagram illustrating a sample control OLED structure comprising a gradient refractive index ITO anode formed on a flat glass substrate.

FIG. 6(a) is a schematic diagram illustrating a sample OLED structure comprising a normal ITO anode formed on a textured glass substrate of an example embodiment.

FIG. 6(b) is a schematic diagram illustrating a sample OLED structure comprising a gradient refractive index ITO anode formed on a textured glass substrate of an example embodiment.

FIG. 7 is a graph of current density (mA/cm²) J vs voltage (V) V of fabricated samples for performance comparison.

FIG. 8 is a graph of luminence (cd/cm²) L vs voltage (V) V of fabricated samples for performance comparison.

FIG. 9 is a graph of efficiency (cd/A) E vs voltage (V) V of fabricated samples for performance comparison.

FIG. 10 is a graph of reflectance (%) vs wavelength (nm) for performance comparison.

FIG. 11 is a graph of contrast ratio (CR) vs luminous reflectance (%) R_{L} for performance comparison.

FIG. 12 is a schematic flowchart for illustrating a method for forming a light emissive device structure in an example embodiment.

### DETAILED DESCRIPTION

In the example embodiments described herein, a high contrast in OLED/PLED displays may be achieved by preferably fabricating a light emissive device such as an OLED using a gradient refractive index transparent conducting material, e.g. transparent conducting oxide (TCO), electrode (e.g. an anode) on a transparent textured substrate.

For example, one side of the substrate comprises a surface having an irregularly textured morphology or having an integral diffuser profile. In the example embodiments, the gradient refractive index TCO anode is deposited on the opposite side of the substrate with a smooth surface.

In the example embodiments, enhancement in light contrast can be attributed to the textured substrate. The textured substrate is textured for diffusing ambient light incident on the transparent substrate.

Furthermore, preferably, a gradient refractive index TCO layer may be used in the example embodiments as an optically destructive layer to reduce the surface reflection of the device.

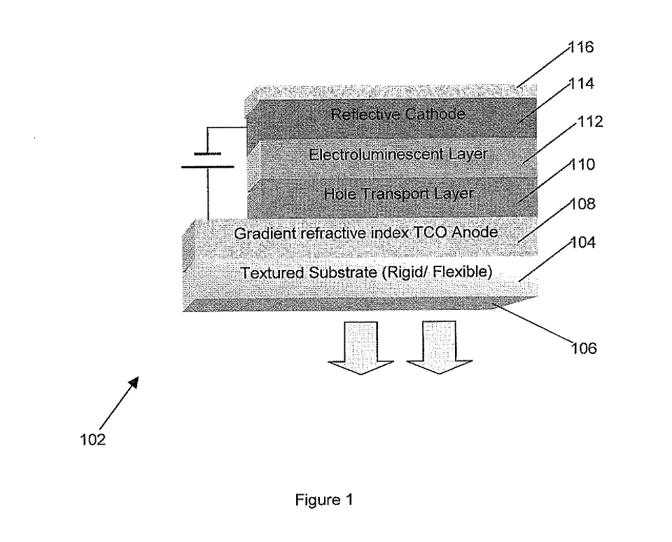

FIG. 1 is a schematic side view diagram of an organic light emitting device (OLED) in a preferred example embodiment. The OLED 102 comprises a textured substrate 104 having a textured surface 106, a gradient refractive index transparent electrode 108 formed on another surface of the textured substrate 104, a hole transport layer 110 formed on the electrode 108, an electroluminescent layer 112 formed on the hole transport layer 110, a reflective electrode 114 formed on the electroluminescent layer 112 and an encapsulation layer 116 formed on the reflective electrode 114. The electrode 108 can be an anode or a cathode depending on e.g. emission orientation. For description purposes, the encapsulation layer is not shown for the other example embodiments.

In the example embodiment, the textured substrate 104 can be a rigid or flexible transparent substrate. The gradient refractive index transparent electrode 108 comprises a gradient refractive index translucent layer that is either electrically conductive or insulative that is first formed on the textured substrate 104 and a transparent conducting material layer e.g. TCO layer functioning primarily as an electrode that is formed on the gradient refractive index translucent layer. The hole transport layer 110 comprises an organic layer. The electroluminescent layer 112 can comprise an organic emissive layer formed over the hole transport layer 110, an organic electron-transporting layer formed over the emissive layer and a thin electron-injector formed over the electron-transporting layer. The reflective electrode 114 comprises a metallic layer.

In the preferred example embodiment, the combination of the gradient refractive index transparent TCO electrode 108 and the textured substrate 104 results in a significant reduction in ambient light reflection from the mirror-like surface of the metallic reflective electrode 114.

In the following description, a number of example embodiments are described showing how the textured surface 106 can be formed. It will be appreciated by a person skilled in the art that other methods can also be used to form irregularly/regularly textured surfaces. These methods include, but are not limited to, micro/nano imprinting, chemical, physical and mechanical processes.

In an example embodiment, a textured surface can be formed on a substrate using a bead blasting technique.

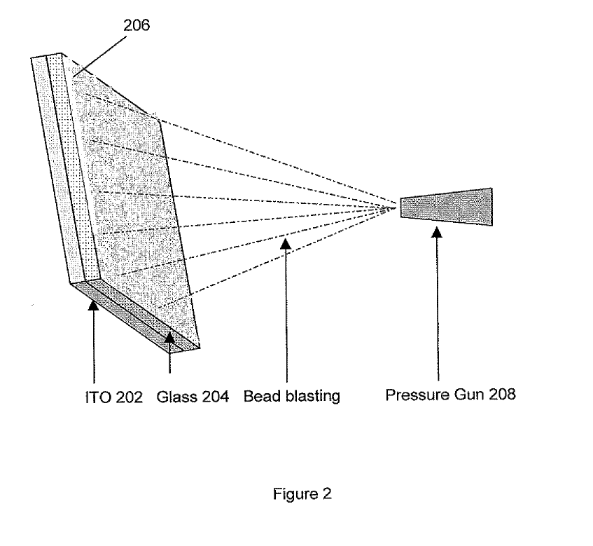

FIG. 2 is a schematic diagram illustrating the bead blasting technique in the example embodiment. A TCO layer 202 comprising e.g. ITO material is formed on a surface of a glass substrate 204. In the example embodiment, the TCO layer 202 can function as an optically destructive electrode or as a gradient refractive index layer to a separate electrode layer. The other surface 206 of the substrate 204 is subjected to bead blasting by a pressure gun 208.

The glass surface 206 is modified/processed by a stream of fine glass beads fired through the pressure gun 208. The average surface roughness can be controlled by process conditions such as the bead sizes and blasting pressure etc. By using different air pressures, e.g. ranging from 35 to 80 pounds per square inch (psi), and using different bead sizes (e.g. ranging from 125 and 180 micron each), the surface roughness of the glass substrate surface 206 can be varied from tenths of a micro-inch up to hundreds of a micro-inch.

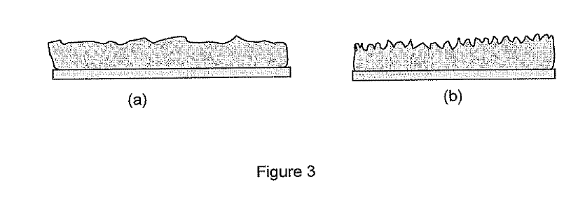

FIG. 3(a) is a schematic side view diagram showing the surface 206 having a surface roughness of tenths of a micro-inch.

FIG. 3(b) is a schematic side view diagram showing the surface 206 having a surface roughness of hundreds of a micro-inch.

As shown in FIGS. 3(a) and (b), the surface 206 has an irregular textured morphology.

In the example embodiment, the glass substrate 204 and/or the pressure hose/gun 208 can be moved in repetitive motions to achieve desired roughness on the surface 206. In the example embodiment, the distance between the glass substrate 204 and the pressure gun 208 is about 6 inches apart at a vertical of about 90 degrees.

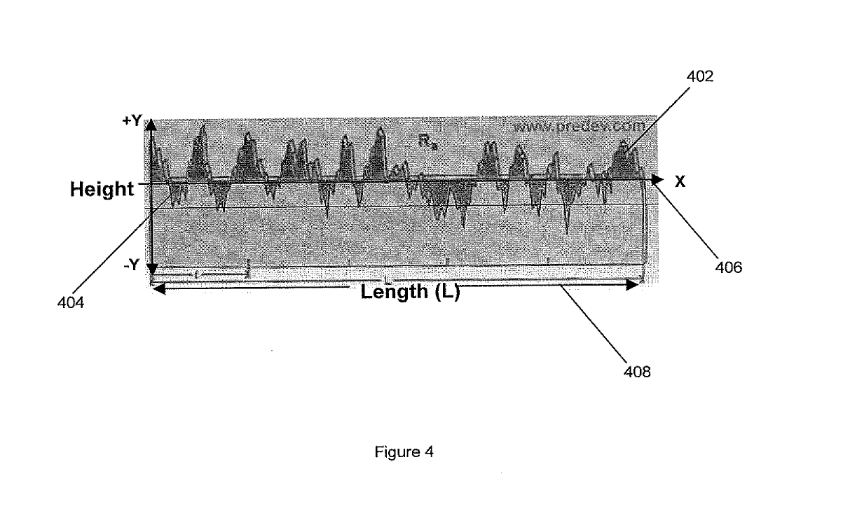

FIG. 4 is a graph illustrating measurement of average roughness Ra. The average roughness, Ra, is defined as the sum of the areas above and below (e.g. 402, 404) the mean surface line 406 divided by the length of the measurement line L 408.

In another example embodiment, a textured surface can be formed on a substrate using a sand blasting technique.

The sand blasting technique is similar to the bead blasting technique. However, sand particles (or fine particles) used in the sand blasting technique is substantially smaller than the glass beads used in the bead blasting technique. In the example embodiment, the process pressures for projecting the sand particles to achieve similar irregular textured surfaces as in the sand blasting technique are also different.

In yet another example embodiment, a textured surface can be formed on a substrate using a sand paper lapping technique.

In the example embodiment, a variety of sand papers or similar materials are used to roughen a glass substrate surface using mechanical polishing matching. The motion is repetitive, for example, a forward or a backward rectilinear motion. Lapping can also be carried out when the substrate traverses in one direction only or in either directions. It will be appreciated that a substantially identical lapping effect can also be created by keeping the glass substrate stationary while a sand paper is in motion on the substrate surface.

After describing how a textured surface can be formed on a substrate, an example embodiment is provided below describing forming/depositing of other layers/structures of an OLED device.

In a preferred example embodiment, a gradient refractive index transparent conducting material, e.g. TCO, layer (compare 202 of FIG. 2) is formed on a surface of the substrate that is opposite the textured surface of the substrate. For description purposes, the TCO material used in the example embodiment is ITO.

In the example embodiment, the gradient refractive index layer functioning as an integrated electrode, e.g. as an anode, comprises a highly oxygen deficient ITO film. The gradient refractive index ITO film can have light-absorbing properties. The light-absorbing ITO layer is deposited using RF magnetron sputtering in a presence of a reducing species of hydrogen ions during film preparation. The sputtering is carried out in an argon-hydrogen gas mixture. The refractive index of the ITO film can be tailored accordingly by varying the hydrogen partial pressure in the argon-hydrogen gas mixture.

Alternatively, the light-absorbing ITO layer can be prepared using other thin film deposition techniques under oxygen-deficient conditions. These techniques include, but are not limited to, DC magnetron sputtering, reactive thermal evaporation, e-beam, physical vapour deposition (PVD), chemical vapor deposition (CVD) etc.

In the example embodiment, the thickness of the gradient refractive layer can be in a range of about 10 nm to a few hundred nanometers, depending on the type of light-absorbing materials (ie. ITO or any organic or inorganic semiconducting material that can serve the purpose of light absorbing) and the corresponding desired refractive indices.

In the example embodiment, the gradient refractive index ITO electrode comprises, at its surface, a high transparent top ITO layer with a relatively high work-function to enhance hole-injection. The deposition process of this top ITO layer is also carried out in a hydrogen-argon gas mixture but with a lower hydrogen partial pressure. The thickness of this top ITO layer is kept constant at about 130 nm for device applications. This can allow hole-injection properties in OLEDs made with different gradient refractive index anode combinations to be compared.

In the example embodiment, after forming the gradient refractive index layer/electrode, an organic stack (compare 110, 112 of FIG. 1) is deposited on the gradient refractive index layer/electrode.

For applications with OLED structures, organic materials of N,N′-bis(1-naphthyl)-N,N′-diphenyl-1,1′-biphenyl-4,4′-diamine (NPB-hole transporting layer) and Tris [8-hydroxyquinolinato]aluminum (Alq3-emissive layer) are deposited by thermal evaporation. The organic layers can also be deposited by other methods including, but not limited to, PVD, CVD and other deposition techniques.

For applications with PLED structures, layers of polymeric materials e.g. poly (3,4-ethylenedioxythiophene) poly(styrenesulfonate) (PEDOT:PSS) as a hole-transporting layer and phenyl-substituted poly(phenylenevinylene) (Ph-PPV) as an emissive layer, are deposited by spin coating. Other solution processable methods such as, but not limited to, screen-printing, inkjet printing, stamping and nano imprinting may also be used. The thickness of polymer layers can be controlled over a range of about 10-200 nm. Further, modified interlayers can be deposited between the organic layers using similar deposition techniques. In addition, small molecule organic materials and dendrimer emitters can also be deposited by solution process technology.

In the example embodiment, after forming the organic stack (compare 110, 112 of FIG. 1), an electrode (compare 114 of FIG. 1), e.g. as a cathode, is formed on the organic stack.

Electrode materials, such as LiF/Al, Mg, Ca and other low work function metals, are deposited by thermal evaporation in the example embodiment. The electrode may also be prepared by techniques such as, but not limited to, sputtering, e-beam evaporation, PVD, CVD or a combination of these processes or any other possible deposition techniques. In the example embodiment, this electrode comprises Ca/Ag. The thickness of Ca is in the range of about to nm to about 50 nm. The thickness of Ag is in the range of about 50 nm to about 500 nm.

Next, to compare the performances of devices incorporating the described example embodiments against typical devices, experimental and control OLED samples were fabricated.

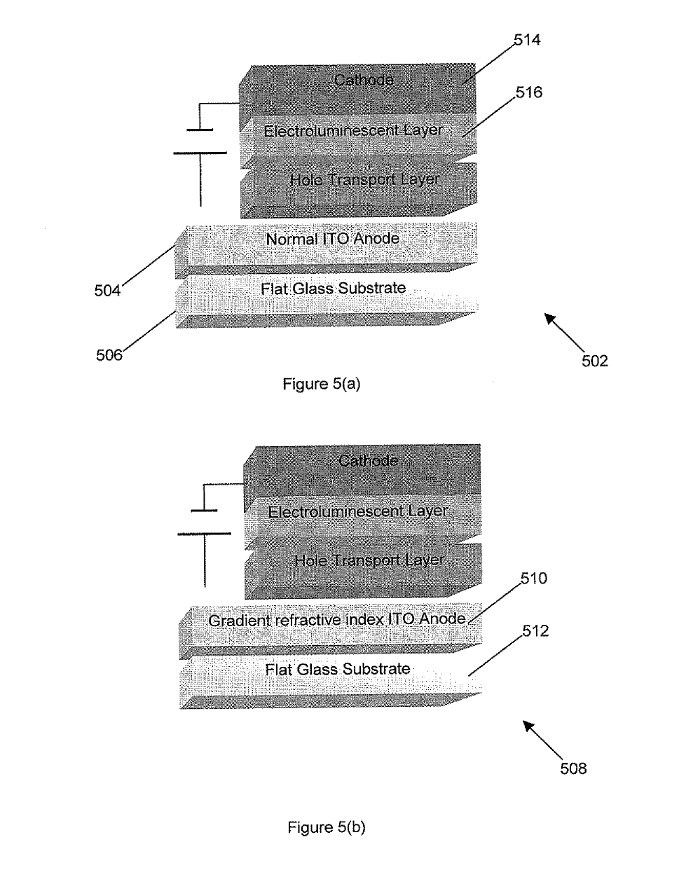

FIG. 5(a) is a schematic diagram illustrating a sample control OLED structure 502 comprising a normal ITO anode 504 formed on a flat glass substrate 506. FIG. 5(b) is a schematic diagram illustrating a sample control OLED structure 508 comprising a gradient refractive index ITO anode 510 formed on a flat glass substrate 512.

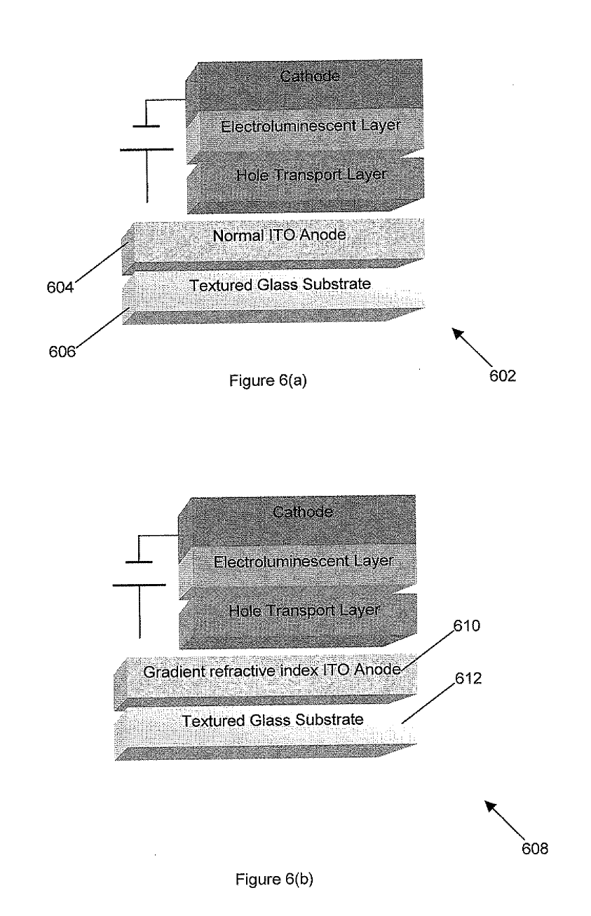

FIG. 6(a) is a schematic diagram illustrating a sample OLED structure 602 comprising a normal ITO anode 604 formed on a textured glass substrate 606 of an example embodiment. FIG. 6(b) is a schematic diagram illustrating a sample OLED structure 608 comprising a gradient refractive index ITO anode 610 formed on a textured glass substrate 612 of an example embodiment. The textured substrates 606, 612 have a surface roughness of about 190 micro inch.

For the performance comparison, the different gradient refractive index ITO anodes (e.g. 510 of FIG. 5, 610 of FIG. 6) were deposited on the smooth side of the glass substrates using RF magnetron sputtering. The substrates 506, 508, 606, 612 of FIG. 5 and FIG. 6 were not heated during and after film deposition. The substrate temperature, inherently raised due to the plasma process during the film deposition, was lower than about 80° C. in this investigation. However, the gradient refractive index ITO can be formed at substrate above 80 C depending on the applications. The base pressure in the sputtering system was about 2.0×10⁻⁴ Pa. The thin films of ITO can be fabricated by controlling the film deposition conditions. For example, by varying the hydrogen partial pressure in the sputtering gas mixture, it is possible to optimize the optical and electrical properties of the ITO films.

It has been recognized by the inventors that the low temperature deposition process developed for the gradient refractive index ITO anodes e.g. 510, 610 of FIG. 5 and FIG. 6 is also suitable for flexible OLEDs/PLEDs comprising plastic foils that are typically not compatible with a high temperature plasma process.

Current density-luminance-voltage (J-L-V) characteristics were measured with a Keithley 2420 source measure unit in a glove box purged with nitrogen gas. Reflectance of the OLED samples was measured using a UV-VIS-NIR spectrophotometer.

In the following figures, G-ITO is used in the legend to represent gradient refractive index ITO.

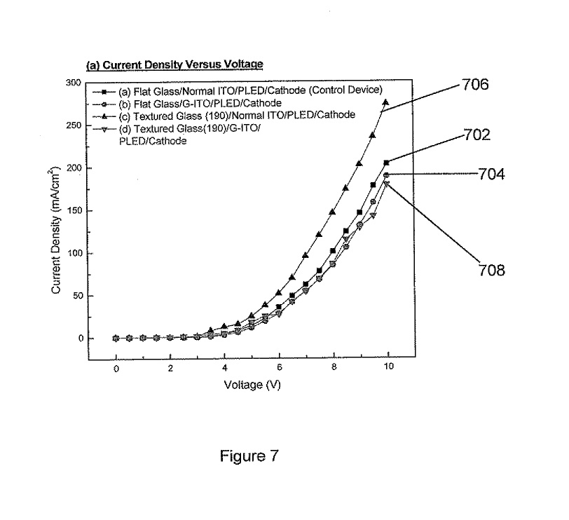

FIG. 7 is a graph of current density (mA/cm²) J vs voltage (V) V of the fabricated samples for performance comparison. Plot 702 shows the results for the sample control OLED structure 502 (FIG. 5). Plot 704 shows the results for the sample OLED control structure 508 (FIG. 5). Plot 706 shows the results for the sample OLED structure 602 (FIG. 6). Plot 708 shows the results for the sample OLED structure 608 (FIG. 6).

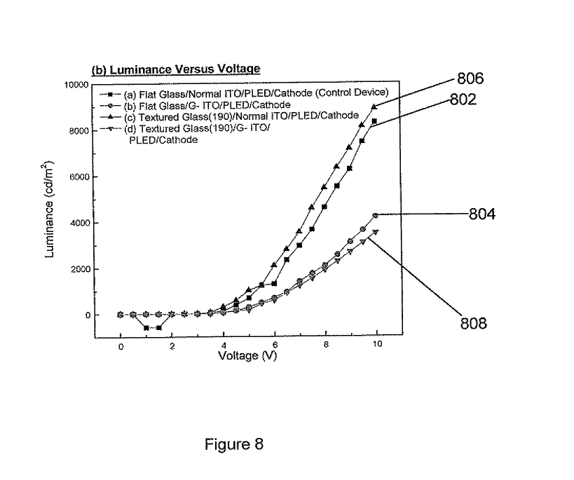

FIG. 8 is a graph of luminance (cd/cm²) L vs voltage (V) V of the fabricated samples for performance comparison. Plot 802 shows the results for the sample control OLED structure 502 (FIG. 5). Plot 804 shows the results for the sample control OLED structure 508 (FIG. 5). Plot 806 shows the results for the sample OLED structure 602 (FIG. 6). Plot 808 shows the results for the sample OLED structure 608 (FIG. 6).

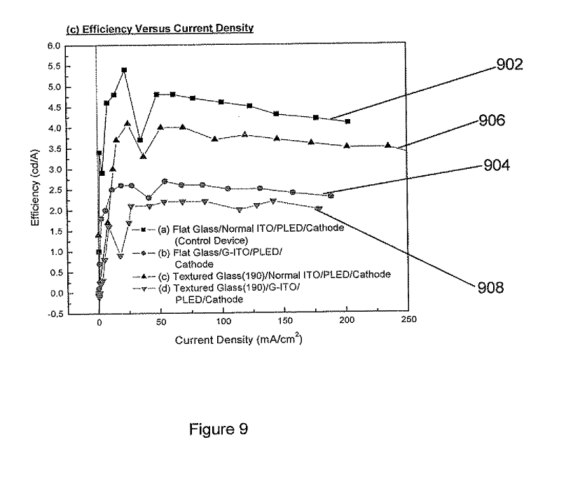

FIG. 9 is a graph of efficiency (cd/A) E vs voltage (V) V of the fabricated samples for performance comparison. Plot 902 shows the results for the sample control OLED structure 502 (FIG. 5). Plot 904 shows the results for the sample control OLED structure 508 (FIG. 5). Plot 906 shows the results for the sample OLED structure 602 (FIG. 6). Plot 908 shows the results for the sample OLED structure 608 (FIG. 6).

From FIG. 7, it can be seen that the J-V relationships are substantially identical at low drive voltages and deviate slightly at higher drive voltages except for plot 706 (ie. for sample control OLED structure 602 of FIG. 6) where it can be seen that there is a significant increase of current density at higher drive voltages.

It can be observed from the L-V and E-J curves shown in FIGS. 8 and 9 respectively, that the luminance and the luminous efficiency for the OLED samples made with gradient refractive index ITO anodes fabricated on flat glass and textured glass substrates are relatively lower as compared to the samples with normal ITO on flat glass substrates and normal ITO on textured glass substrates (ie. compare 804 vs 802, 808 vs 806 of FIGS. 8 and 904 vs 902, 908 vs 906 of FIG. 9 respectively). The reduced luminescence of the OLED samples 508 of FIG. 5, 608 of FIG. 6 comprising gradient refractive index ITO is attributed to the lower transmittance of the anodes 510 of FIG. 5, 610 of FIG. 6 respectively, since the gradient refractive index ITO anodes 510 of FIG. 5, 610 of FIG. 6 are semitransparent and can also partially absorb the emitted light. In contrast, for example, in the sample control OLED structure 502 of FIG. 5, the cathode at 514 strongly reflects emitted light from the EL layer at 516, thereby contributing in a significant increase of brightness (see 802 of FIG. 8) and poor contrast of the structure 502. Further, it can be seen from the electroluminescence results of FIG. 8, that there is an increase in light emission (see plot 806) for the OLED sample comprising normal ITO on textured glass (ie. structure 602 of FIG. 6) as compared to that (see plot 802) of structure 502 of FIG. 5 (ie. comprising normal ITO on a flat glass substrate) at the same forward bias and having similar current density. This is due to the light out coupling effect, which helps to enhance the light output from the OLED samples. This light out coupling effect can be attributed to the textured glass substrate used for structure 602 (FIG. 6).

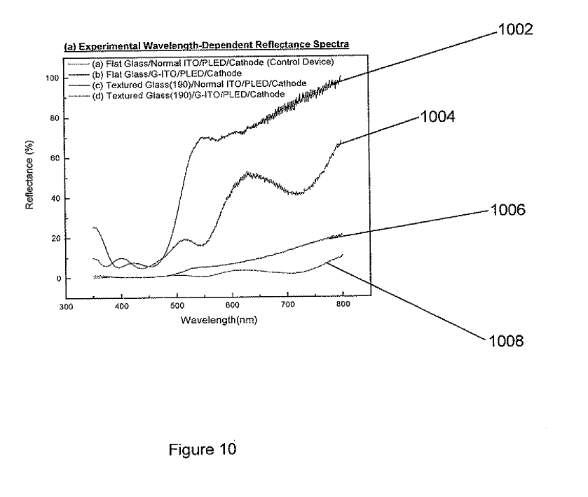

FIG. 10 is a graph of spectral reflectance (%) vs wavelength (nm) for performance comparison. The wavelength range is about 350 nm to about 800 nm. Plot 1002 shows the spectral reflectance measured for the sample control OLED structure 502 (FIG. 5). Plot 1004 shows the spectral reflectance measured for the sample control OLED structure 508 (FIG. 5). Plot 1006 shows the spectral reflectance measured for the sample OLED structure 602 (FIG. 6). Plot 1008 shows the spectral reflectance measured for the sample OLED structure 608 (FIG. 6).

By comparing the structures 502 of FIGS. 5 and 602 of FIG. 6, ie. having a substantially identical OLED structure fabricated on different substrates (ie. a flat glass substrate versus a textured glass substrate), it can be observed that the overall device reflectance decreases substantially (compare 1002 vs 1006). The integrated spectral reflectance of an OLED sample can be calculated using the following relationship:

$${R}_{L} = \frac{\int R ( λ ) F ( λ ) d λ}{\int F ( λ ) d λ} , \qquad ( 1 )$$

where R(λ) is the spectral reflectance of the thin film system of the OLED sample and F(λ) is the flux of incident illumination. According to eq. (1), the integrated spectral reflectances calculated for the sample structures 502, 508 of FIGS. 5 and 602, 608 of FIG. 6 are about 55.7%, 29.7%, 7% and 2% respectively.

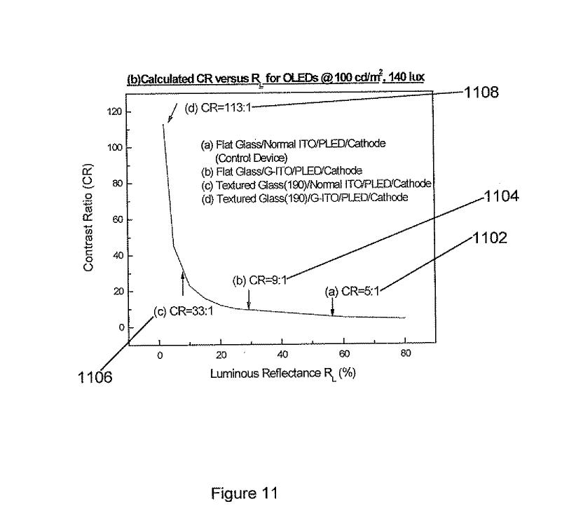

FIG. 11 is a graph of contrast ratio (CR) vs luminous reflectance (%) R_{L} for performance comparison. For this graph, calculated contrast ratio as a function of luminous reflectance is shown at about 100 cd/m² under about 140 lux of ambient illuminance. The CR at 1102 is calculated for the sample control OLED structure 502 (FIG. 5). The CR at 1104 is calculated for the sample OLED structure 508 (FIG. 5). The CR at 1106 is calculated for the sample control OLED structure 602 (FIG. 6). The CR at 1108 is measured for the sample OLED structure 608 (FIG. 6).

From FIG. 11, it can be observed that the contrast ratio CR of the sample structure 502 of FIG. 5, ie. a conventional OLED structure on flat glass substrate, is about 5:1. It can also be observed that the sample structure 602 of FIG. 6 (ie. comprising normal ITO on glass having an irregular surface texture) has a higher contrast ratio in comparison with that of the sample structure 502 of FIG. 5 ie. the contrast ratio of the devices is increased up to about 30:1 under about 100 cd/A and about 140 lux ambient illumination (compare 1102 and 1106). The contrast ratio can be further increased up to about 100:1 (see 1108) for the sample structure 608 of FIG. 6 ie. when a OLED structure is fabricated comprising a gradient refractive index ITO anode on a textured glass substrate. Thus, it can be observed from FIG. 10 and FIG. 11 that the sample structure 608 of FIG. 6 can enhance the contrast of an OLED display when operated under high ambient illumination.

Table 1 below tabulates the device performance for the sample structures 502, 508 of FIGS. 5 and 602, 608 of FIG. 6. The table shows a comparison of integrated spectral reflectance, contrast ratio, turn-on voltage and luminous efficiency of the sample structures.

TABLE 1

| | | Average | |
|---|---|---|---|
| | | Surface roughness | |
| | | (Ra) (micro inch) | |
| | | Zero | 190 |
| Type of ITO | | (Flat | (Textured |
| Anode | | Glass) | Glass) |
| Low Temperature ITO | Integrated | 55.7 | 7 |
| (Normal/typical ITO) | Reflectance (%) | | |
| ITO film thickness: about | Contrast Ratio | 5:1 | 33:1 |
| 130 nm | Turn-on Voltage at | 4.0 | 3.6 |
| Sheet Resistance: about | 100 cd/m² (V) | | |
| 26 Ω/□ | Maximum | 4.8 | 4.1 |
| | Luminous | | |
| | Efficiency (cd/A) | | |
| Gradient Refractive | Integrated | 29.7 | 2 |
| Index ITO (Gradient | Reflectance (%) | | |
| refractive index ITO) | Contrast Ratio | 9:1 | 113:1 |
| [(5% H₂ in Ar] flow | Turn-on Voltage at | 4.5 | 4.5 |
| rate = 9, 7, 5 sccm | 100 cd/m² (V) | | |
| (15 mins)/1 sccm (30 mins)] | Maximum | 2.7 | 2.2 |
| ITO film thickness: about | Luminous | | |
| 303 nm | Efficiency (cd/A) | | |
| Sheet Resistance: about | | | |
| 28 Ω/□ | | | |

Therefore, the above performance comparison indicates that, preferably, integration of a gradient refractive index ITO anode with a transparent textured substrate can provide high contrast OLEDs. Further, a substrate with a textured surface functioning to diffuse light can enhance light output from OLEDs.

An example embodiment can provide a PLED/OLED device comprising a rigid or flexible transparent substrate, a gradient refractive index translucent layer that can be electrically conductive or insulating, a TCO layer formed over the gradient refractive index translucent layer, an organic hole-transporting layer formed over the TCO layer, an organic emissive layer formed over the hole-transporting layer, an organic electron-transporting layer formed over the emissive layer, an thin electron-injector formed over the electron-transporting layer, a metallic cathode layer formed over the electron-injector and an encapsulation layer.

The transparent substrate can be glass or clear plastic foils with a permeation barrier layer suitable for OLED/PLED applications. The transparent substrate is textured or provided with a reflection suppressing element or layer comprising rough or irregularly textured surface topography. The gradient refractive index translucent layer can comprise one or more organic or inorganic layers. The gradient refractive index electrode has a thickness in the range of about 10 nm to about 400 nm. The gradient refractive index electrode is formed using TCO materials. A gradient refractive index transparent electrode can be formed using one individual TCO material or in a combination of different TCOs. The oxygen deficient TCO layer can be made by sputtering, thermal evaporation and other thin film deposition techniques. The textured substrate can be integrated with a gradient refractive index electrode for enhancing the contrast ratio of OLED/PLED displays. The textured substrate is able to improve the OLED light output. This textured substrate can be used for OLED/PLED and other emissive displays to reduce the ambient reflectance and hence improve the contrast ratio of the displays. The TCO layer material is selected from a group consisting indium tin oxide (ITO), zinc aluminum oxide, indium zinc oxide, tin oxide, Ga—In—Sn—O (GITO), Zn—In—Sn—O (ZITO), Ga—In—O (GIO), Zn—In—O (ZIO), other TCOs and carbon nanotube (CNT) that are suitable for use as an anode in a PLED/OLED and an emissive device. These materials can be used individually or with a combination of different materials. The thickness of the TCO layer can be adjusted. The electron injector is formed of a low work-function metal or metal alloy. The low work-function metal and metal alloy is selected from a group consisting Ca, Li, Ba, Mg. The electron injector is formed of a thin bilayer of LiF/Al or CSF/Al or Mg/Ag or Ca/Ag. If a reflective anode is used in a top-emitting OLED/PLED, a TCO with a refractive index gradient can also be used as an gradient refractive index cathode for enhancing the visual legibility of the top-emitting OLED/PLED display.

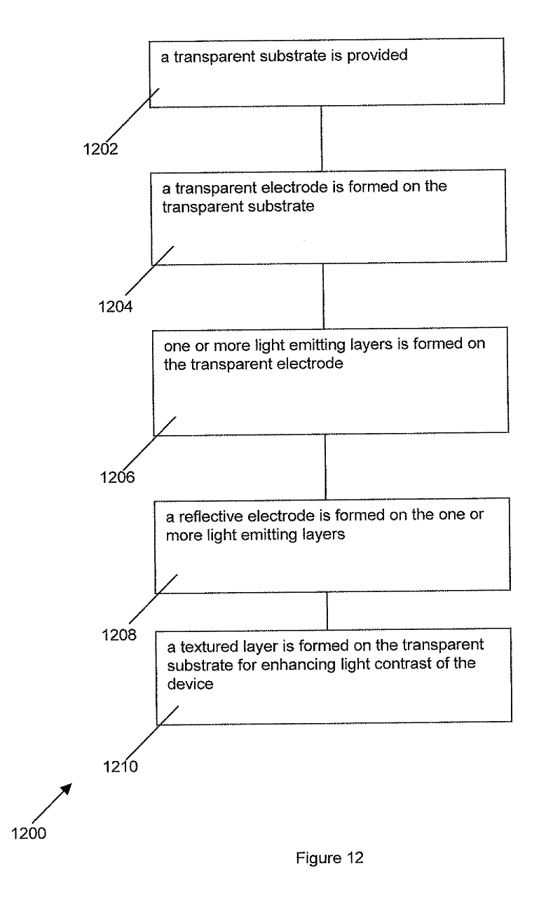

FIG. 12 is a schematic flowchart 1200 for illustrating a method for forming a light emissive device structure in an example embodiment. At step 1202, a transparent substrate is provided. At step 1204, a transparent electrode is formed on the transparent substrate. At step 1206, one or more light emitting layers is formed on the transparent electrode. At step 1208, a reflective electrode is formed on the one or more light emitting layers. At step 1210, a textured layer is formed on the transparent substrate for enhancing light contrast of the device.

The above described example embodiments can provide an integration of a gradient refractive index TCO anode with a transparent substrate having textured features provided on one surface. The example embodiments can be effective in reducing the reflection of the ambient light and hence improving the contrast of OLEDs/PLEDs. In the described example embodiments, the refractive index of the TCO anode can be engineered by controlling the film deposition conditions, while the textured surface provided on a transparent substrate can be created using e.g. chemical, physical or mechanical techniques. The results from fabricated samples show that the contrast of OLEDs/PLEDs made using the example embodiments can be controlled by adjusting the oxygen deficiency in the ITO anode and the substrate surface roughness, e.g. surface roughness of the glass substrate can be varied from tenths of a micro-inch up to hundreds of a micro-inch. It has been demonstrated that the contrast ratio of an OLED/PLED can be further increased up to about 100:1, at about 100 cd/m² and about 140 lux, when a substrate provided with a textured surface and combined with an gradient refractive index TCO anode is used. The results also show that the visual contrast of OLEDs/PLEDs made using the example embodiments may also be a function of the surface roughness of the reflection suppressing element and the process conditions of the gradient refractive index TCO anode.

Further, the above described example embodiments can provide contrast enhancement of OLEDs and can be relatively simple and low cost. The above described example embodiments can be integrated easily with existing device fabrication processes. The above described example embodiments can offer a way to fabricate high contrast OLED displays without acquiring any additional equipment or process modification currently being using for OLED fabrication. The above described example embodiments can be applicable for OLEDs/PLEDs with a variety of device architectures, e.g., bottom emission, top-emitting and inverted device architectures. In addition, the above described example embodiments can be used for enhancing visual contrast in light emitting displays, such as, but not limited to, OLED/PLED and other emissive devices on rigid and flexible substrates.

It will be appreciated by a person skilled in the art that numerous variations and/or modifications may be made to the present invention as shown in the specific embodiments without departing from the spirit or scope of the invention as broadly described. The present embodiments are, therefore, to be considered in all respects to be illustrative and not restrictive.

For example, while TCO has been disclosed in the example embodiment as the material for the gradient refractive index electrode, other materials may be used, including, but not limited to, a material combination of TCO and carbon nanotubes (CNT).

1. A light emissive device structure, the structure comprising,
a transparent substrate;
a transparent electrode formed on the transparent substrate;
one or more light emitting layers formed on the transparent electrode;
a reflective electrode formed on the one or more light emitting layers; and
a textured layer formed on the transparent substrate for enhancing light contrast of the device.

2. The structure as claimed in claim 1, further comprising a gradient refractive index layer.

3. The structure as claimed in claim 2, wherein the gradient refractive index layer is capable of suppressing light reflection of the light emissive device structure.

4. The structure as claimed in claim 2 or 3, wherein the gradient refractive index layer functions as the transparent electrode.

5. The structure as claimed in any one of claims 2 to 4, wherein the gradient refractive index layer comprises a transparent conducting oxide (TCO) layer.

6. The structure as claimed in claim 5, wherein the TCO layer comprises an oxygen deficient TCO material.

7. The structure as claimed in any one of the preceding claims, wherein the textured layer is formed on an outer surface of the transparent substrate.

8. The structure as claimed in any one of the preceding claims, wherein the textured layer is formed as a surface modification of the transparent substrate.

9. The structure as claimed in claim 8, wherein the textured layer is textured using a chemical technique, physical technique or both.

10. A method for forming a light emissive device structure, the method comprising,
providing a transparent substrate;
forming a transparent electrode on the transparent substrate;
forming one or more light emitting layers on the transparent electrode;
forming a reflective electrode on the one or more light emitting layers; and
forming a textured layer on the transparent substrate for enhancing light contrast of the device.

11. The method as claimed in claim 10, further comprising forming a gradient refractive index layer.

12. The method as claimed in claim 11, wherein the gradient refractive index layer is capable of suppressing light reflection of the light emissive device structure.

13. The method as claimed in claim 11 or 12, wherein the gradient refractive index layer functions as the transparent electrode.

14. The method as claimed in any one of claims 11 to 13, wherein the gradient refractive index layer comprises a transparent conducting oxide (TCO) layer.

15. The method as claimed in claim 14, wherein the TCO layer comprises an oxygen deficient TCO material.

16. The method as claimed in any one of claims 10 to 15, wherein the textured layer is formed on an outer surface of the transparent substrate.

17. The method as claimed in any one of claims 10 to 16, wherein the textured layer is formed as a surface modification of the transparent substrate.

18. The method as claimed in claim 17, wherein the textured layer is textured using a chemical technique, physical technique or both.
